(19) United States
(12) Patent Application Publication
(10) Pub. No.: US 2026/0243289 A1
(43) Pub. Date: Aug. 20, 2026

(54) RIVET FOR USE IN SEMICONDUCTOR MODULE ARRANGEMENT, METHOD FOR PRODUCING A RIVET, AND METHOD FOR CONNECTING RIVET TO A SUBSTRATE

(71) Applicant: Infineon Technologies AG, Neubiberg (DE)

(72) Inventors: Lukas Meis, Büren (DE); Daniel Pielsticker, Paderborn (DE); Guido Strotmann, Anröchte (DE); Florian Dreps, Paderborn (DE)

(73) Assignee: Infineon Technologies AG, Neubiberg (DE)

(21) Appl. No.: 19/536,450

(22) Filed: Feb. 11, 2026

(30) Foreign Application Priority Data
Feb. 14, 2025 (DE) 102025105521.1

(51) Int. Cl. F16B 19/10; B21J 15/02; B21J 15/36

(52) U.S. Cl. CPC F16B 19/1054; B21J 15/02; B21J 15/027; B21J 15/36

(57) ABSTRACT

A method for connecting a rivet to a substrate of a semiconductor module arrangement includes providing a chain of rivets to a joining tool, moving the joining tool to a defined position on the substrate, separating a rivet forming an end of the chain of rivets from the chain of rivets, and connecting the separated rivet to the substrate by means of the joining tool.

### PRIORITY CLAIM

This application claims priority under 35 U.S.C. § 119(b) to German patent application 102025105521.1, filed on February 14, 2025.

### TECHNICAL FIELD

The instant disclosure relates to a rivet for use in a semiconductor module arrangement, to a method for producing a rivet, and to a method for connecting a rivet to a substrate of a semiconductor module arrangement.

### BACKGROUND

Power semiconductor module arrangements often include a base plate within a housing. At least one substrate is arranged on the base plate. A semiconductor arrangement including a plurality of controllable semiconductor elements (e.g., two IGBTs in a half-bridge configuration) is arranged on each of the at least one substrate. Each substrate usually comprises a substrate layer (e.g., a ceramic layer), a first metallization layer deposited on a first side of the substrate layer and, optionally, a second metallization layer deposited on a second side of the substrate layer. The controllable semiconductor elements are mounted, for example, on the first metallization layer. The second metallization layer is usually attached to the base plate by means of a solder layer or a sintering layer. The substrate and the semiconductor elements mounted thereon may be electrically coupled to the outside of the housing by means of terminal elements, for example. Such terminal elements may comprise or may be formed by a simple connection pin. In order to attach a terminal element to the substrate, a rivet may be permanently attached to the substrate, e.g., by means of a solder connection or a welded, and the connection pin may be inserted into the rivet such that the rivet fits over and encompasses a first end of the connection pin. A second end of the connection pin may protrude out of the housing such that the connection pin can be electrically contacted from the outside of the housing. A semiconductor module arrangement usually comprises a plurality of terminal elements.

There is a need for a method for producing rivets for semiconductor module arrangements easily and at low costs, and for a method for connecting such rivets to a substrate of a semiconductor module arrangement easily and at low costs, resulting in reduced costs of the semiconductor module arrangement including such rivets.

### SUMMARY

A method for producing a rivet for a semiconductor module arrangement includes arranging a meal sheet in a stamping tool, wherein the metal sheet has a length in a first direction that is significantly larger than a height of the metal sheet in a second direction perpendicular to the first direction, and performing a stamping process by means of the stamping tool, thereby forming a chain of successive rivets, each rivet of the plurality of rivets including a tubular part and a collar formed at one end of the tubular part, and a plurality of coupling joints, wherein each coupling joint of the plurality of coupling joints connects two directly successive rivets to each other, and wherein each coupling joint of the plurality of coupling joints forms a predetermined breaking point, or each coupling joint of the plurality of coupling joints is configured to be cut through by means of a cutting tool.

A chain of rivets for a semiconductor module arrangement includes a plurality of successive rivets, each rivet of the plurality of rivets including a tubular part and a collar formed at one end of the tubular part, and a plurality of coupling joints, wherein each coupling joint of the plurality of coupling joints connects two directly successive rivets to each other, each coupling joint of the plurality of coupling joints forms a predetermined breaking point, or each coupling joint of the plurality of coupling joints is configured to be cut through by means of a cutting tool, and the plurality of rivets and the plurality of coupling joints are integrally formed in one piece.

A method for connecting a rivet to a substrate of a semiconductor module arrangement includes providing a chain of rivets to a joining tool, moving the joining tool to a defined position on the substrate, separating a rivet forming an end of the chain of rivets from the chain of rivets, and connecting the separated rivet to the substrate by means of the joining tool.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional view of a semiconductor module arrangement.

FIG. 2 schematically illustrates a three-dimensional view of a rivet produced by means of a method according to embodiments of the disclosure.

FIG. 3, including FIGS. 3A to 3D, schematically illustrates top views of rivets produced by means of a method according to embodiments of the disclosure.

FIG. 4 schematically illustrates a cross-sectional view of a rivet produced by means of a method according to embodiments of the disclosure.

FIG. 5 schematically illustrates a three-dimensional view of an exemplary chain formed by a plurality of rivets produced by means of a method according to embodiments of the disclosure.

FIG. 6 schematically illustrates a three-dimensional view of another exemplary chain formed by a plurality of rivets produced by means of a method according to embodiments of the disclosure.

FIG. 7 schematically illustrates a three-dimensional view of an even further example of a chain formed by a plurality of rivets produced by means of a method according to embodiments of the disclosure.

FIG. 8 schematically illustrates a step of a method for connecting a rivet to a substrate of a semiconductor module arrangement according to embodiments of the disclosure.

FIG. 9 schematically illustrates another step of the method for connecting a rivet to a substrate of a semiconductor module arrangement according to embodiments of the disclosure.

FIG. 10, including FIGS. 10A to 10C, schematically illustrates different steps of a method for forming rivets for a semiconductor module arrangement according to embodiments of the disclosure.

### DETAILED DESCRIPTION

In the following detailed description, reference is made to the accompanying drawings. The drawings show specific examples of how the invention can be implemented. It is to be understood that the features and principles described with respect to the various examples may be combined with each other, unless specifically noted otherwise. In the description, as well as in the claims, designations of certain elements as “first element”, “second element”, “third element” etc. are not to be understood as enumerative. Instead such designations serve solely to denote different “elements”. That is, e.g., the existence of a “third element” does not necessarily require the existence of a “first element” or a “second element”. An electrical line or electrical connection as described herein may be a single electrically conductive element, or include at least two individual electrically conductive elements connected in series and/or parallel. Electrical lines and electrical connections may include metal and/or semiconductor material and may be permanently electrically conductive (i.e., non-switchable). A semiconductor body as described herein may be made of (doped) semiconductor material and may be a semiconductor chip or be included in a semiconductor chip. A semiconductor body has electrically connectable pads and includes at least one semiconductor element with electrodes.

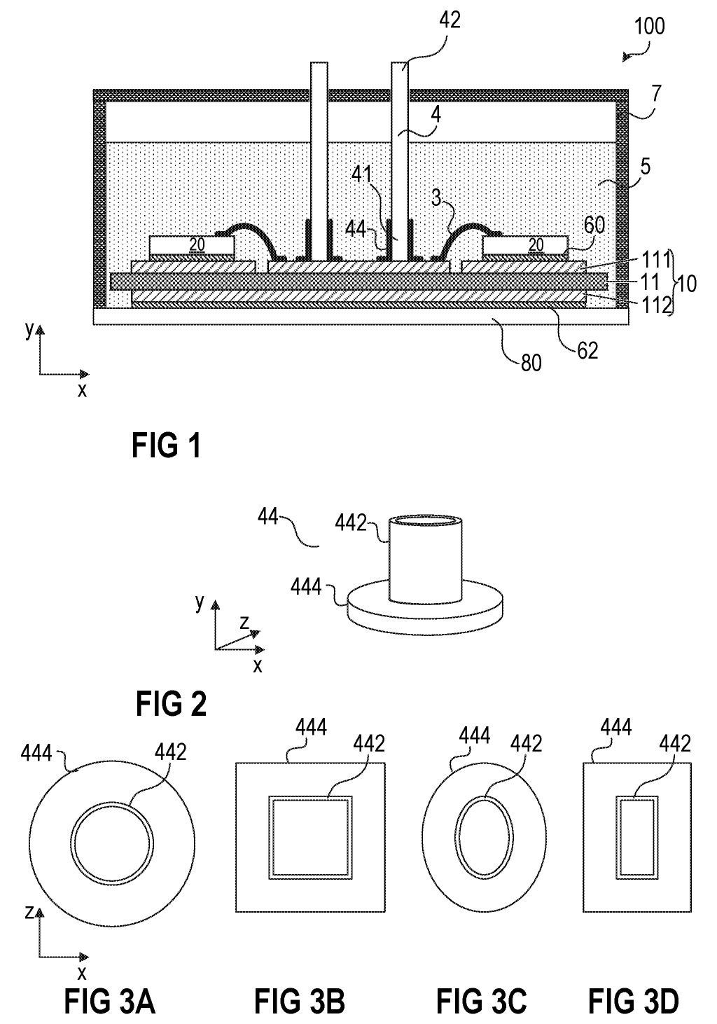

Referring to FIG. 1, a cross-sectional view of a semiconductor module arrangement 100 is illustrated. The semiconductor module arrangement 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. Alternatively, the dielectric insulation layer 11 may consist of an organic compound and include one or more of the following materials: Al₂O₃, AlN, SiC, BeO, BN, or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, SiN or BN and may have a diameter of between about 1µm and about 50µm. The substrate 10 may also be a conventional printed circuit board (PCB) that has a non-ceramic dielectric insulation layer 11. For instance, a non-ceramic dielectric insulation layer 11 may consist of or include a cured resin.

The substrate 10 is arranged in a housing 7. In the example illustrated in FIG. 1, the substrate 10 is arranged on a base plate 80 which forms a base surface of the housing 7, while the housing 7 itself solely comprises sidewalls and (optionally) a cover. In some semiconductor module arrangements 100, more than one substrate 10 is arranged on the same base plate 80 and within the same housing 7. The base plate 80 may comprise a layer of a metallic material such as, e.g., copper or AlSiC. Other materials, however, are also possible. The base plate 80, however, may also be omitted. According to other examples, a substrate 10 itself may form a base surface of the housing 7. According to other examples, the housing 7 may comprise a base surface, sidewalls, and (optionally) a cover, and one or more substrates 10 may be arranged on the base surface provided by the housing 7.

One or more semiconductor bodies 20 may be arranged on the at least one substrate 10. Each of the semiconductor bodies 20 arranged on the at least one substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable semiconductor element.

The one or more semiconductor bodies 20 may form a semiconductor arrangement on the substrate 10. In FIG. 1, only two semiconductor bodies 20 are exemplarily illustrated. The second metallization layer 112 of the substrate 10 in FIG. 1 is a continuous layer. According to another example, the second metallization layer 112 may be a structured layer. According to other examples, the second metallization layer 112 may be omitted altogether. The first metallization layer 111 is a structured layer in the example illustrated in FIG. 1. “Structured layer” in this context means that the respective metallization layer is not a continuous layer, but includes recesses between different sections of the layer. Such recesses are schematically illustrated in FIG. 1. The first metallization layer 111 in this example includes three different sections. Different semiconductor bodies 20 may be mounted to the same or to different sections of the first metallization layer 111. Different sections of the first metallization layer may have no electrical connection or may be electrically connected to one or more other sections using electrical connections 3 such as, e.g., bonding wires. Semiconductor bodies 20 may be electrically connected to each other or to the first metallization layer 111 using electrical connections 3, for example. Electrical connections 3, instead of bonding wires, may also include bonding ribbons, connection plates or conductor rails, for example, to name just a few examples. The one or more semiconductor bodies 20 may be electrically and mechanically connected to the substrate 10 by electrically conductive connection layers 60. Such electrically conductive connection layers 60 may be solder layers, layers of an electrically conductive adhesive, or layers of a sintered metal powder, e.g., a sintered silver (Ag) powder, for example.

The semiconductor module arrangement 100 illustrated in FIG. 1 further includes terminal elements 4. The terminal elements 4 provide an electrical connection between the inside and the outside of the housing 7. The terminal elements 4 may be electrically connected to the first metallization layer 111 with a first end 41, while a second end 42 of the terminal elements 4 protrudes out of the housing 7. The terminal elements 4 may be electrically contacted from the outside at their second ends 42. Arranging the terminal elements 4 centrally on the substrate 10 is only an example. According to other examples, terminal elements 4 may be arranged closer to or adjacent to the sidewalls of the housing 7. The first end 41 of a terminal element 4 may be electrically and mechanically connected to the substrate 10 by means of a (hollow) rivet 44, as is illustrated in FIG. 1. A rivet 44 may be electrically and mechanically coupled to the first metallization layer 111 of the substrate 10 by means of an electrically conductive connection layer (not specifically illustrated for the rivets 44 in FIG. 1). Such an electrically conductive connection layer may be a solder layer, a layer of an electrically conductive adhesive, or a layer of a sintered metal powder, e.g., a sintered silver (Ag) powder, for example. Rivets 44, however, may also be electrically and mechanically coupled to the first metallization layer 111 by means of a welded connection. A welded connection may be formed by means of any kind of welding technique such as, e.g., ultrasonic welding, laser welding, or resistance welding.

A rivet 44 generally comprises a tubular part, and the first end 41 of the terminal element 4 may be inserted into the tubular part of the rivet 44. The rivet 44, therefore, encloses the first end 41 of the terminal element 4, when the terminal element 4 is inserted in the rivet 44. The connection formed between the terminal element 4 and the rivet 44, therefore, may not be permanent, as the terminal element 4 may be removed from the rivet 44 without destroying the terminal element 4 and the rivet 44. However, the rivet 44 may fit tightly around the terminal element 4 so as to provide a stable electrical connection between the two parts.

The rivet 44, in addition to the tubular part, may further comprise a collar arranged at a first end of the tubular part and terminating the tubular part in the vertical direction y. The first end of the tubular part, when the rivet 44 is arranged on the substrate 10, faces towards the substrate 10 such that the collar is arranged on the first metallization layer 111. A dimension (e.g., radius or outer diameter) of such a collar in a horizontal direction (perpendicular to the vertical direction y) is generally larger than a dimension (e.g., outer diameter) of the tubular part in the same direction. The collar therefore increases the surface area of the rivet 44 and, consequently, the connecting surface between the rivet 44 and the substrate 10. This results in a much more stable connection between the rivet 44 and the substrate 10.

The semiconductor module arrangement 100 may further include an encapsulant 5. The encapsulant 5 may consist of or include a silicone gel or may be a rigid molding compound, for example. The encapsulant 5 may at least partly fill the interior of the housing 7, thereby covering the components and electrical connections that are arranged on the substrate 10. The terminal elements 4 may be partly embedded in the encapsulant 5. At least their second ends 42, however, are not covered by the encapsulant 5 and protrude from the encapsulant 5 through the housing 7 to the outside of the housing 7. The encapsulant 5 is configured to protect the components and electrical connections of the semiconductor module arrangement 100, in particular the components arranged inside the housing 7, from certain environmental conditions and mechanical damage. It is generally also possible to omit the housing 7 and solely protect the substrate 10 and any components mounted thereon with an encapsulant 5. In this case, the encapsulant 5 may be a rigid material, for example.

Semiconductor module arrangements often include a plurality of terminal elements 4. That is, a significant number of rivets 44 may be required to connect the plurality of terminal elements 4 to the substrate 10. Therefore, by reducing the costs for a single rivet 44 and by further reducing the time and number of tools required for connecting the rivets 44 to the substrate 10, the overall costs for a semiconductor module arrangement may be reduced. The costs for a rivet 44 can be reduced, for example, if the rivet 44 can be produced in a fast and efficient way. In the following, methods will be described that allow forming a rivet 44 for a semiconductor module arrangement 100 in a fast and efficient way and at low costs. Further, methods will be described that allow connecting rivets 44 produced by means of such method to a substrate 10 in a fast and efficient way and at low costs.

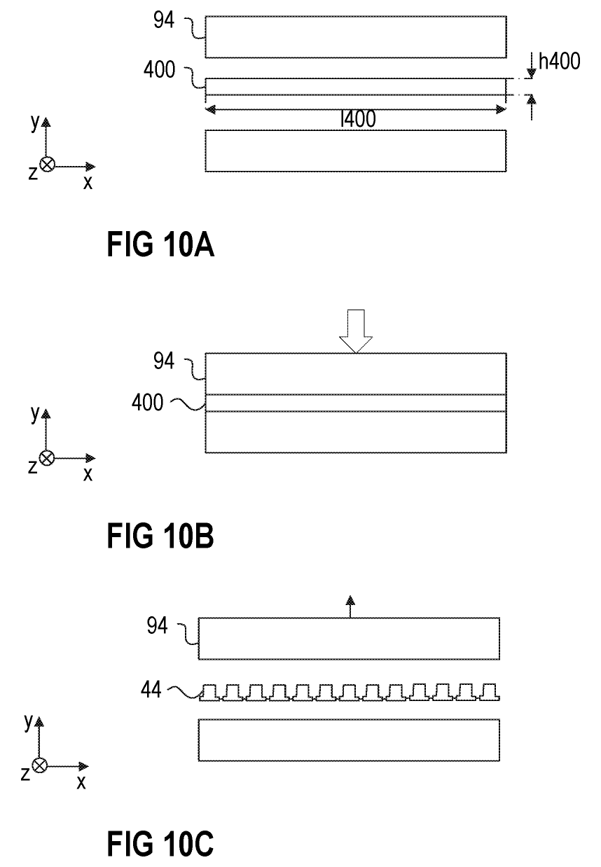

According to embodiments of the disclosure, a method for producing a rivet 44 for a semiconductor module arrangement comprises arranging a meal sheet 400 in a stamping tool 94, wherein the metal sheet 400 has a length l400 in a first direction that is significantly larger than a height h400 of the metal sheet 400 in a second direction perpendicular to the first direction. The method further comprises performing a stamping process by means of the stamping tool 94, thereby forming a chain of successive rivets 44, each rivet 44 of the plurality of rivets 44 comprising a tubular part 442 and a collar 444 formed at one end of the tubular part 442, and a plurality of coupling joints 446, wherein each coupling joint 446 of the plurality of coupling joints 446 connects two directly successive rivets 44 to each other, and wherein each coupling joint 446 of the plurality of coupling joints 446 forms a predetermined breaking point, or each coupling joint 446 of the plurality of coupling joints 446 is configured to be cut through by means of a cutting tool. Such method is schematically illustrated by means of FIGS. 10A – 10C. The length l400 of the metal sheet 400 may be at least 20 times, at least 50 times, or at least 100 times greater than its height h400.

Known rivets are generally formed as a single piece and are often produced by means of, e.g., stamping or deep drawing processes. Such processes are often complex, and the throughput is comparably low. The resulting rivets, therefore, are rather expensive. When using the claimed method, a chain formed by a plurality of successive rivets 44 is produced. Two directly adjoining rivets 44 are connected to each other by means of coupling joints, wherein the coupling joins form predetermined breaking points, or wherein the coupling joints may be cut through easily and with little amount of force by means of a cutting tool. Using the method for producing rivets for a semiconductor module arrangement described herein, a large number of rivets 44 can be manufactured in comparably short time. The process is a simple stamping process. This reduces the costs for each of the individual rivets 44 manufactured by means of the method described herein.

According to some examples, and as is schematically illustrated in FIGS. 10A to 10C, the entire metal sheet may be reshaped in a single stamping process. However, this may require the stamping tool 94 to be comparably large in order to be able to reshape a long metal sheet 400 in only one step. If the stamping tool 94 is comparably small, the metal sheet 400 may only have a defined maximum length l400 in order to completely fit into the stamping tool 94. Only a comparably low number of rivets might be formed in a single stamping process, if the metal sheet 400 is comparably short. Therefore, according to further embodiments of the disclosure, the metal sheet 400 may be stamped section by section. That is, in a first step, a first section of a metal sheet 400 may be inserted into the stamping tool 94, and a stamping step may follow. Subsequently, a second section of the same metal sheet 400 directly adjoining the first section may be inserted into the stamping tool 94, and a further stamping step may follow. In this way, the entire metal sheet 400 may be reshaped in two or even more separate steps. A resulting chain of rivets 44 may comprise at least 50 rivets 44, or at least 100 rivets 44, for example.

The metal sheet 400, in a third direction z that is perpendicular to the first direction x and the second direction y, may have a width that essentially equals a width of the resulting chain of rivets 44. That is, a single (exactly one, not more than one) chain of rivets 44 may be produced during the stamping process. Alternatively, however, it is also possible that a width of the metal sheet 400 in the third direction z essentially equals a multiple of the width of a resulting chain of rivets 44. That is, a plurality of chains of rivets 44 may be produced in a single stamping process. When performing the stamping process, the different chains of rivets 44 may be separated from each other. That is, the metal sheet 400 may have an essentially square or rectangular shape, for example.

A chain of rivets 44 for a semiconductor module arrangement comprises a plurality of successive rivets 44, each rivet 44 of the plurality of rivets 44 comprising a tubular part 442 and a collar 444 formed at one end of the tubular part 442, and a plurality of coupling joints 446. Each coupling joint 446 of the plurality of coupling joints 446 connects two directly successive rivets 44 to each other. Each coupling joint 446 of the plurality of coupling joints 446 forms a predetermined breaking point, or each coupling joint 446 of the plurality of coupling joints 446 is configured to be cut through by means of a cutting tool, and the plurality of rivets 44 and the plurality of coupling joints 446 are integrally formed in one piece. This is schematically illustrated in FIGS. 5, 6 and 7, which each show a subset of the plurality of rivets 44 forming a chain of rivets 44.

A single rivet 44 produced by means of a method according to embodiments of the disclosure is exemplarily illustrated in the three-dimensional view of FIG. 2. The rivet 44 in this example has been separated from the chain of rivets 44. The collar 444 of a rivet 44 generally has a round cross-section. The same applies for the tubular part 442, which also generally has a round cross-section. However, it is generally also possible that the collar 444 of each rivet 44 of the chain of rivets 44 has an oval cross-section, a square cross-section, or a rectangular cross-section. The same applies for the tubular part 42 which may also have an oval cross-section, a square cross-section, or a rectangular cross-section. Any other suitable shapes are generally also possible. This is schematically illustrated in the top views of FIGS. 3A – 3D, wherein FIG. 3A shows a collar 444 having a round cross-section and a tubular part 442 having a round cross section, FIG. 3B shows a collar 444 having a square cross-section and a tubular part 442 having a square cross section, FIG. 3C shows a collar 444 having an oval cross-section and a tubular part 442 having an oval cross section, and FIG. 3D shows a collar 444 having a rectangular cross-section and a tubular part 442 having a rectangular cross section. The different shapes as illustrated in FIGS. 3A – 3D, however, can also be combined with each other. For example, a collar 444 may have a square cross-section, while the tubular part 442 has a round cross-section, the collar 444 may have a rectangular cross-section, while the tubular part 442 has an oval cross-section, and so on. While many different shapes are generally possible, the collar 444 having a square or rectangular cross-section may be advantageous in some cases, as a square or rectangular collar 444 provides a comparably large connection surface.

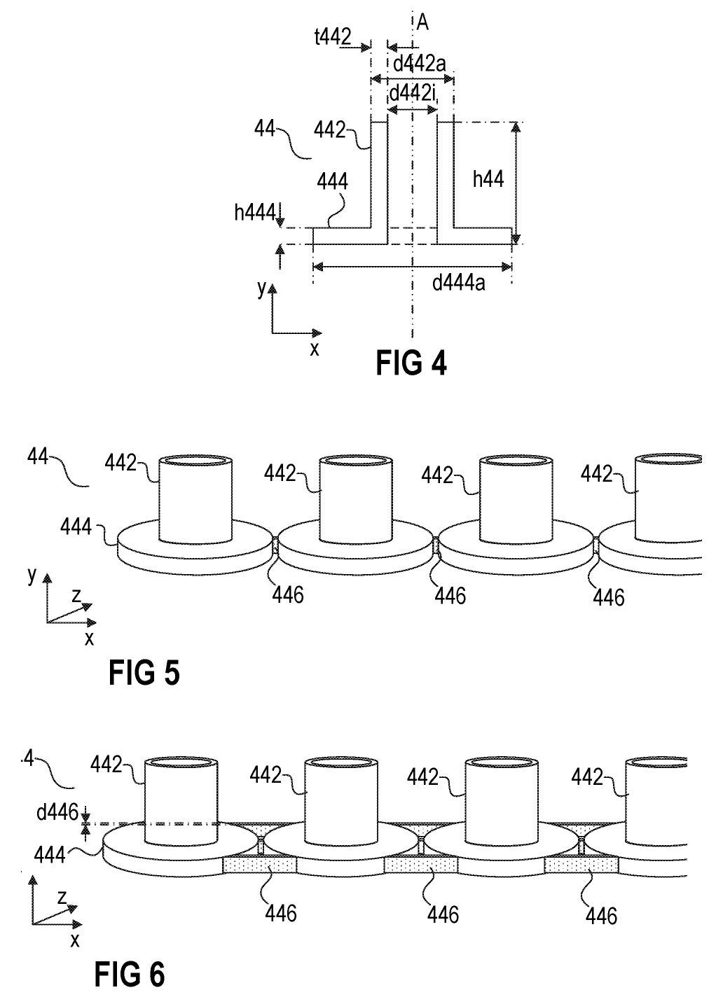

The tubular part 442 may extend centrally from the collar 444. That is, a center axis A of the collar 444 may be identical with a center axis A of the tubular part 442. FIG. 4 schematically illustrates a cross-sectional view of a single rivet 44. A diameter d442a of the tubular part 442 may be between 1mm and 2mm, for example. The diameter d442a of the tubular part 442 generally refers to an outer diameter. That is, the diameter d442a is the maximum diameter (or maximum dimension if cross-section is not round) of the tubular part 442 and is defined by a diameter of the outer surface of the tubular part 442. The tubular part 442 generally also has an inner diameter d442i. The inner diameter d442i is a diameter of a hole extending through the tubular part 442 and is defined by a diameter of an inner surface of the tubular part 442, opposite the outer surface. The inner diameter d442i of the tubular part 442 may be between 0.5mm and 1mm, for example. A difference between the outer diameter d442a and the inner diameter d442i defines a wall thickness t442 of the tubular part 442. A wall thickness (d442a – d442i) may be between 0.1mm and 0.5mm, for example. A height h44 of the rivet 44 (collar 444 and tubular part 442) along the center axis A (in the vertical direction y) may be between 0.8mm and 3mm, for example. A height h444 of the collar 444 may be between 0.1mm and 0.5mm, for example. A diameter d444a of the collar 444 may be between 1.8mm and 3mm, for example. The different dimensions mentioned herein, however, are only examples. The rivets 44 produced by means of the methods according to the embodiments disclosed herein may generally have any other suitable shapes and dimensions.

The tubular part 442 may be open at least towards one direction. In particular, the tubular part 442 may be open at least at a second end, the second end facing away from the collar 444. In this way, a terminal element 4 may be inserted into the tubular part 442 from the second side. The tubular part 442 may also be open at its first end. That is, the hole extending through the tubular part 442 may be open on two sides (through hole). It is, however, also possible that the hole extending through the tubular part 442 is a blind hole that is closed at the first end. This is schematically illustrated by means of dashed lines in FIG. 4.

Conventional rivets 44 generally have a height of between 2.5mm and 3mm. However, a height of between 0.8mm and 3mm, or between 0.8mm and 2.5mm, or even between 0.8mm and 1.5mm is generally sufficient to adequately connect a terminal element 4 to the substrate 10. Rivets 44 of lower height (e.g., between 0.8mm and 2.5mm, or between 0.8mm and 1.5mm) may be more easily produced by means of the methods according to the embodiments disclosed herein.

Each coupling joint 446 may extend between the collar 444 of one of the rivets 44 and the collar 444 of a directly successive rivet 44. Referring to FIGS. 4, 5, and 6, each coupling joint 446 of the plurality of coupling joints 446 may comprise one or more bars, each bar of the one or more bars having a first end connected to one rivet 44 and a second end connected to a directly successive rivet 44 in the chain of rivets 44. In the example illustrated in FIG. 5, each coupling joint 446 comprises a single bar (exactly one, not more than one) extending centrally between the respective rivets 44. In the example illustrated in FIG. 6, each coupling joint 446 comprises three bars, wherein one bar extends centrally between the respective rivets 44. The other bars extend on opposite sides with respect to the centrally arranged bar and are equally spaced apart from the centrally arranged bar. In the example illustrated in FIG. 7, each coupling joint 446 comprises two bars. The arrangement of FIG. 7 is similar to the arrangement of FIG. 6, wherein the centrally arranged bar has been omitted. Any other number of bars is generally also possible. Further, one or more bars may be arranged at any suitable positions with respect to the rivets 44.

Each bar of the one or more bars may extend in a first direction between the two respective successive rivets 44, and may have a thickness d446 of 0.5mm or less, or 0.3mm or less in a direction perpendicular to the first direction, and perpendicular to a center axis A of the respective rivet 44. That is, the bars may be comparably thin, such that they can be easily broken or cut through by means of respective cutting tools. Further, each bar may be as short as possible such that a greater number of rivets 44 can be obtained from a single metal sheet 400. Implementing the coupling joints 446 as bars, however, is only an example. Generally, coupling joints 446 can be implemented in any suitable way. The chain of rivets 44 may comprise or consist of aluminum, an aluminum alloy, copper, or a copper alloy. The rivets 44 may alternatively be coated, e.g., by means of a nickel coating.

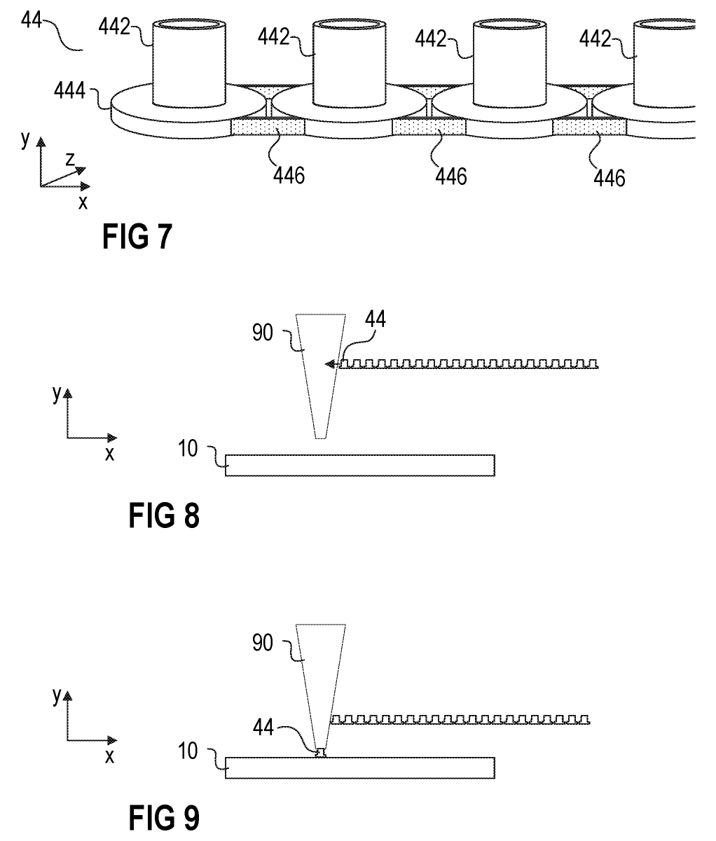

A method for connecting a rivet 44 to a substrate 10 of a semiconductor module arrangement according to embodiments of the disclosure comprises providing a chain of rivets 44 to a joining tool 90, moving the joining tool 90 to a defined position on the substrate 10, separating a rivet 44 forming an end of the chain of rivets 44 from the chain of rivets 44, and connecting the separated rivet 44 to the substrate 10 by means of the joining tool 90. This is schematically illustrated in FIGS. 8 and 9.

By providing a chain of rivets 44 directly to the joining tool, a separate tool configured to pick up an individual rivet 44 and place it on the substrate 10 is no longer required. Once a rivet 44 of the chain of rivets 44 has been connected to the substrate 10, the joining tool 90 may move to a next position on the substrate 10, separate another rivet 44 from the chain of rivets 44, and connect this rivet 44 to the substrate 10. In this way, a greater number of rivets 44 can be connected to the substrate 10 by means of a single tool, thereby reducing the production time and the overall costs of the semiconductor substrate arrangement.

After separating a rivet 44 from the chain of rivets 44 and while performing the step of connecting the rivet 44 to the substrate 10, the rivet 44 may be held in a desired position by means of any suitable mechanism. For example, the rivet may be held in a desired position by means of a vacuum mechanism. That is, a vacuum may be created which sucks the rivet 44 towards the joining tool 90. According to another example, a rivet 44 that has been separated from the chain of rivets 44 may be held in a desired position by means of a magnet (e.g., if the rivet 44 comprises or consists of a magnetic material, or is coated with a magnetic material). Other holding mechanisms are generally also possible.

Connecting the rivet 44 to the substrate 10 may comprise performing a welding process. The welding process may be one of an ultrasonic welding process, a laser welding process, and a resistance welding process. That is, for example, the joining tool 90 may be or may comprise a sonotrode. The chain of rivets 44 may be fed to the sonotrode, a rivet 44 may be separated from the chain of rivets 44, and the rivet 44 may then be connected to the substrate 10 performing an ultrasonic welding process (e.g., by vibrating the sonotrode). Welding, however, is only one of several possible examples. It is generally also possible, for example, that the rivets 44 are connected to the substrate 10 by means of a solder process.

Separating a rivet 44 forming an end of the chain of rivets 44 from the chain of rivets 44 may comprise simply breaking the rivet 44 from the chain of rivets 44. As mentioned above, the coupling joints 446 may form predetermined breaking points. Such breaking of a rivet 44 from the chain of rivets 44 can be achieved by means of comparably simple tools. Such tools can be easily attached to or integrated in the joining tool 90, for example.

According to alternative embodiments, separating a rivet 44 forming an end of the chain of rivets 44 from the chain of rivets 44 may comprise cutting the rivet 44 from the chain of rivets 44 by means of a cutting tool. A suitable cutting tool can be easily attached to or integrated in the joining tool 90, for example.

According to some examples, the step of separating a rivet 44 forming an end of the chain of rivets 44 from the chain of rivets 44 and the step of connecting the rivet 44 to the substrate 10 are performed simultaneously. For example, the rivet 44 may be cut from the chain of rivets 44 while connecting the rivet 44 to the substrate 10. It is also possible that the rivet 44 breaks from the chain of rivets 44 while connecting the rivet 44 to the substrate 10. For example, when using an ultrasonic welding process, the coupling joints 446 between the rivet 44 and the directly successive rivet 44 may break due to the vibrations induced by means of the joining tool 90. When connecting the rivet 44 to the substrate 10 by means of a laser welding process, for example, the coupling joint 446 may be cut by means of the same laser that is used to perform the laser welding process. That is, no additional breaking or cutting tool may be required in such cases. According to some examples it is even possible that the rivet 44 is only separated from the chain of rivets 44 after connecting it to the substrate 10.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A method for producing a rivet for a semiconductor module arrangement, comprising:
arranging a meal sheet in a stamping tool, wherein the metal sheet has a length in a first direction that is significantly larger than a height of the metal sheet in a second direction perpendicular to the first direction; and
performing a stamping process by means of the stamping tool, thereby forming a chain of successive rivets, each rivet of the plurality of rivets comprising a tubular part and a collar formed at one end of the tubular part, and a plurality of coupling joints, wherein each coupling joint of the plurality of coupling joints connects two directly successive rivets to each other, and wherein each coupling joint of the plurality of coupling joints forms a predetermined breaking point, or each coupling joint of the plurality of coupling joints is configured to be cut through by means of a cutting tool.

2. The method of claim 1, wherein the length of the metal sheet is at least 20 times greater than its height.

3. A chain of rivets for a semiconductor module arrangement, comprising:
a plurality of successive rivets, each rivet of the plurality of rivets comprising a tubular part and a collar formed at one end of the tubular part; and
a plurality of coupling joints, wherein
each coupling joint of the plurality of coupling joints connects two directly successive rivets to each other,
each coupling joint of the plurality of coupling joints forms a predetermined breaking point, or each coupling joint of the plurality of coupling joints is configured to be cut through by means of a cutting tool, and
the plurality of rivets and the plurality of coupling joints are integrally formed in one piece.

4. The chain of rivets of claim 3, wherein each rivet of the plurality of rivets has a height of between 0.8mm and 3mm.

5. The chain of rivets of claim 3, wherein each coupling joint of the plurality of coupling joints comprises one or more bars, each bar of the one or more bars having a first end connected to one rivet and a second end connected to a directly successive rivet in the chain of rivets.

6. The chain of rivets of claim 5, wherein each bar of the one or more bars extends in a first direction between the two respective successive rivets, and has a thickness of 0.5mm or less in a direction perpendicular to the first direction, and perpendicular to a center axis of the respective rivet.

7. The chain of rivets of claim 3, wherein the chain of rivets comprises aluminum, an aluminum alloy, copper, or a copper alloy.

8. The chain of rivets of claim 3, wherein
the collar of each rivet of the chain of rivets has a round cross-section, an oval cross-section, a square cross-section, or a rectangular cross-section; and/or
the tubular part of each rivet of the chain of rivets has a round cross-section, an oval cross-section, a square cross-section, or a rectangular cross-section.

9. The chain of rivets of claim 3, wherein each coupling joint extends between the collar of one of the rivets and the collar of a directly successive rivet.

10. A method for connecting a rivet to a substrate of a semiconductor module arrangement, comprising:
providing a chain of rivets, the chain of rivets comprising:
a plurality of successive rivets (44), each rivet (44) of the plurality of rivets (44) comprising a tubular part (442) and a collar (444) formed at one end of the tubular part (442); and
a plurality of coupling joints (446), wherein each coupling joint (446) of the plurality of coupling joints (446) connects two directly successive rivets (44) to each other;
moving a joining tool to a defined position on the substrate;
separating a rivet forming an end of the chain of rivets from the chain of rivets; and
connecting the separated rivet to the substrate by means of the joining tool.

11. The method of claim 10, wherein connecting the rivet to the substrate comprises performing a welding process.

12. The method of claim 11, wherein the welding process is one of an ultrasonic welding process, a laser welding process, and a resistance welding process.

13. The method of claim 10, wherein each coupling joint (446) of the plurality of coupling joints (446) forms a predetermined breaking point, and separating a rivet forming an end of the chain of rivets from the chain of rivets comprises breaking the rivet from the chain of rivets.

14. The method of claim 10, wherein separating a rivet forming an end of the chain of rivets from the chain of rivets comprises cutting the rivet from the chain of rivets by means of a cutting tool.

15. The method of claim 10, wherein the step of separating a rivet forming an end of the chain of rivets from the chain of rivets and the step of connecting the rivet to the substrate are performed simultaneously.
